(19) United States
(12) Patent Application Publication
(10) Pub. No.: US 2026/0223360 A1
(43) Pub. Date: Jul. 30, 2026

(54) SEMICONDUCTOR STRUCTURE AND METHOD FOR FORMING THE SAME

(71) Applicant: Winbond Electronics Corp., Taichung City (TW)

(72) Inventors: Jyun-Ming Liao, Tainan (TW); Shu-Ming Li, Kaohsiung City (TW)

(73) Assignee: Winbond Electronics Corp., Taichung City (TW)

(21) Appl. No.: 19/246,558

(22) Filed: Jun. 23, 2025

(30) Foreign Application Priority Data
Jan. 24, 2025 (TW) 114103622

(51) Int. Cl. H10B 12/00; G11C 5/06

(52) U.S. Cl. CPC H10B 12/482; G11C 5/063; H10B 12/485

(57) ABSTRACT

The disclosure provides a semiconductor structure and a method for forming the same. The method includes the following steps. Bit line structures are formed in the substrate, and each includes a bit line and a capping layer formed thereon and protruding above a top surface of the substrate. First spacers are formed on opposite sidewalls of each bit line structure. A second spacer layer covering the first spacers and a top surface of the capping layer is formed on the opposite sidewalls of each bit line structure. Third spacers covering the second spacer layer are formed on the opposite sidewalls of each bit line structure on the top surface of the substrate. A conductive pad layer covering the bit line structures, the third spacers, the second spacer layer and the first spacers is formed on the top surface of the substrate, and then is patterned to form conductive pad structures.

### CROSS-REFERENCE TO RELATED APPLICATION

This application claims the priority benefit of Taiwan application serial no. 114103622 filed on Jan. 24, 2025. The entirety of the above-mentioned patent application is hereby incorporated by reference herein and made a part of this specification.

### BACKGROUND

### Technical Field

The present invention relates to a semiconductor structure and a method for forming the same, and particularly relates to a semiconductor structure for a memory structure and a method for forming the same.

### Description of Related Art

Dynamic random access memory (DRAM) is composed by a large amount of memory cells, and each memory cell includes a capacitor and a transistor (1T1C), wherein a word line is connected to a gate of the transistor, a bit line is connected to a source of the transistor, and the capacitor is connected to a drain of the transistor. As the sizes of the electronic components continue to decrease and the requirements to the performances of the electronic components continue to increase, there is a continuous need for those skilled in the art to fabricate electronic

devices including more components, or to make each component have a smaller area.

### SUMMARY

The present invention provides a method for forming a semiconductor structure in which a third spacer is formed to cover a second spacer layer on opposite sidewalls of each bit line structure on a top surface of a substrate, so that the subsequent patterning processes for forming a plurality of conductive pad structures have an improved process window.

The present invention provides a method for forming a semiconductor structure, which includes following steps: forming a plurality of bit line structures in a substrate, wherein each bit line structure includes a bit line and a capping layer formed on the bit line and protruding above a top surface of the substrate; forming a first spacer on opposite sidewalls of each bit line structure; forming a second spacer layer covering the first spacer and a top surface of the capping layer on opposite sidewalls of each bit line structure; forming a third spacer covering the second spacer layer on opposite sidewalls of each bit line structure on the top surface of the substrate; forming a conductive pad layer covering the bit line structures, the third spacer, the second spacer layer and the first spacer on the top surface of the substrate; and patterning the conductive pad layer to form a plurality of conductive pad structures.

The first spacer includes a first material layer and a second material layer formed on the first material layer. Materials of the first material layer and the second spacer layer are different from materials of the second material layer and the third spacer. The materials of the first material layer and the second spacer layer include nitride, and the materials of the second material layer and the third spacer include oxide.

In a step of patterning the conductive pad layer, a portion of the first spacer, a portion of the second spacer layer, and a portion of the third spacer on one of the opposite sidewalls of each bit line structure are also removed to form a first spacer structure on one of the opposite sidewalls of each bit line structure and to form a second spacer structure on another one of the opposite sidewalls of each bit line structure.

A top surface of the first spacer structure is lower than a top surface of the second spacer structure.

In the step of patterning the conductive pad layer, a portion of each capping layer is also removed, such that the capping layer is formed to include a first portion and a second portion. The first portion has a top surface positioned at a level identical to a level of the top surface of the first spacer structure. The second portion has a top surface positioned at a level lower than a level of the top surface of the second spacer structure.

The method of forming the semiconductor structure further includes: forming an insulation pattern in an opening separating the conductive pad structures, wherein the insulation pattern is in contact with the first spacer structure.

The method of forming the semiconductor structure further includes: before forming the insulation pattern, removing a portion of the second material layer and a portion of the third spacer of the first spacer structure that are exposed by the opening to form recesses.

In a step of forming the insulation pattern, the insulation pattern is formed above the recesses without filling up the recesses, so that air gaps are formed in the recesses.

Each of the conductive pad structures includes an upper portion and a lower portion. The upper portion has a top surface positioned at a level identical to a level of a top surface of the insulation pattern. The lower portion has a top surface positioned at a level identical to a level of the top surface of the first spacer structure.

In the method of forming the semiconductor structure, the third spacer is formed to cover the second spacer layer on opposite sidewalls of each bit line structure on the top surface of the substrate, so that the subsequent patterning processes for forming the conductive pad structures have an improved process window. For example, the third spacer can enhance the tolerance for overlay shift in the patterning processes, so that portions of the conductive pad layer that are intended to be removed will not be remained due to the overlay shift, and the defects such as short circuits can be avoided accordingly.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are schematic cross-sectional views of a method for forming a semiconductor structure according to an embodiment of the present invention.

FIG. 2 is a schematic cross-sectional view of a semiconductor structure according to another embodiment of the present invention.

### DESCRIPTION OF THE EMBODIMENTS

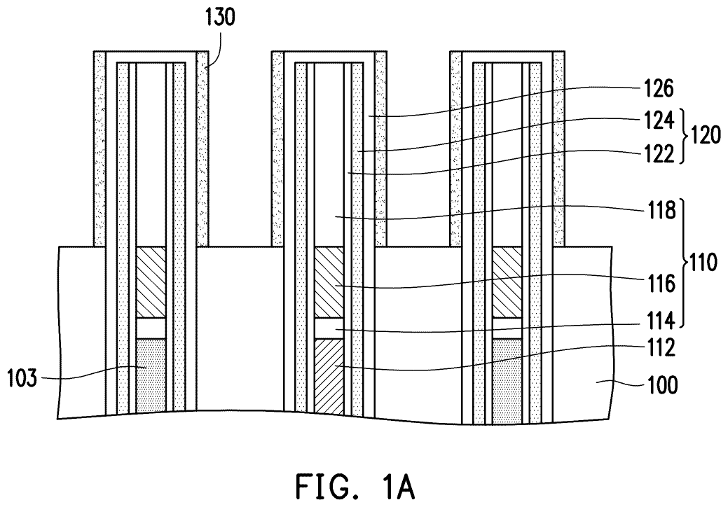

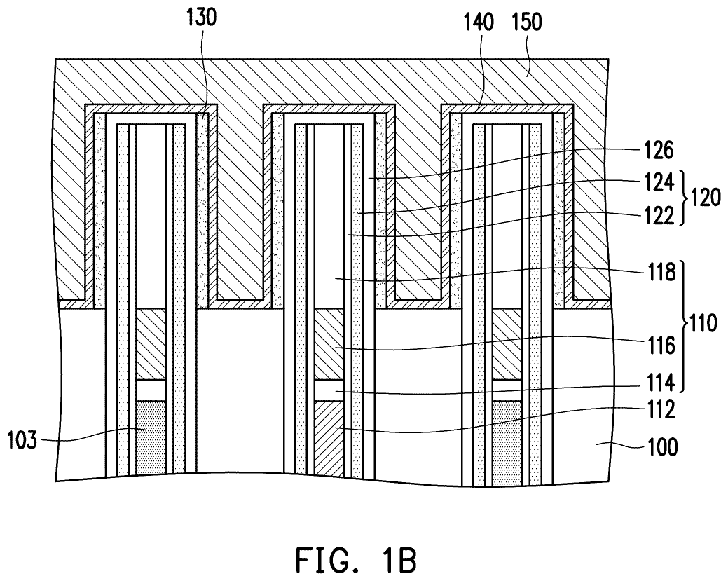

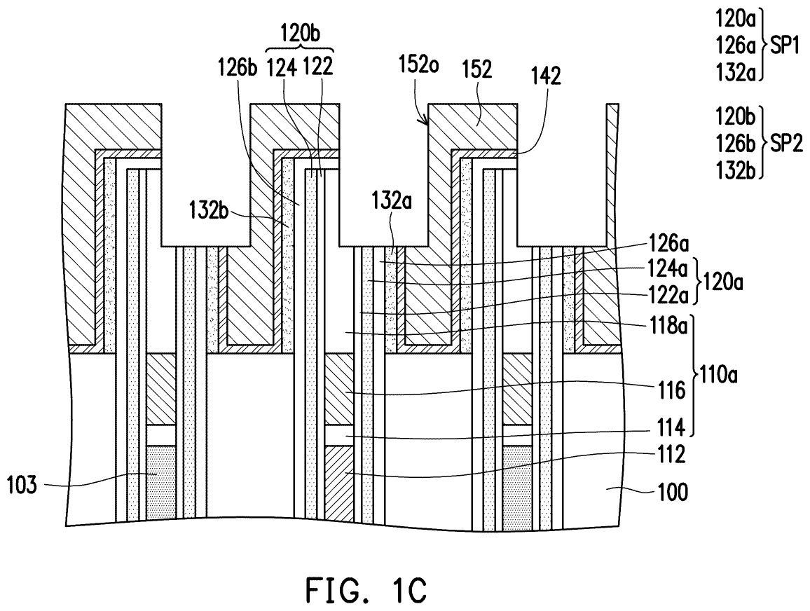

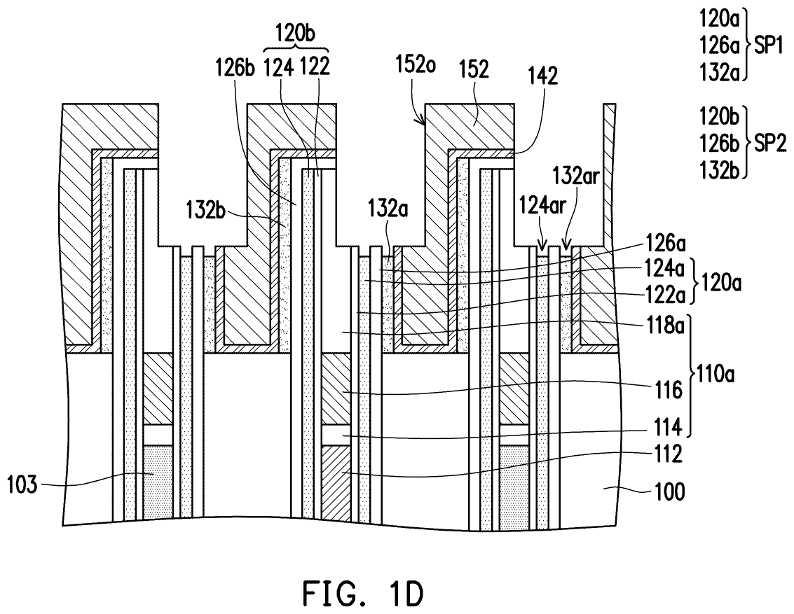

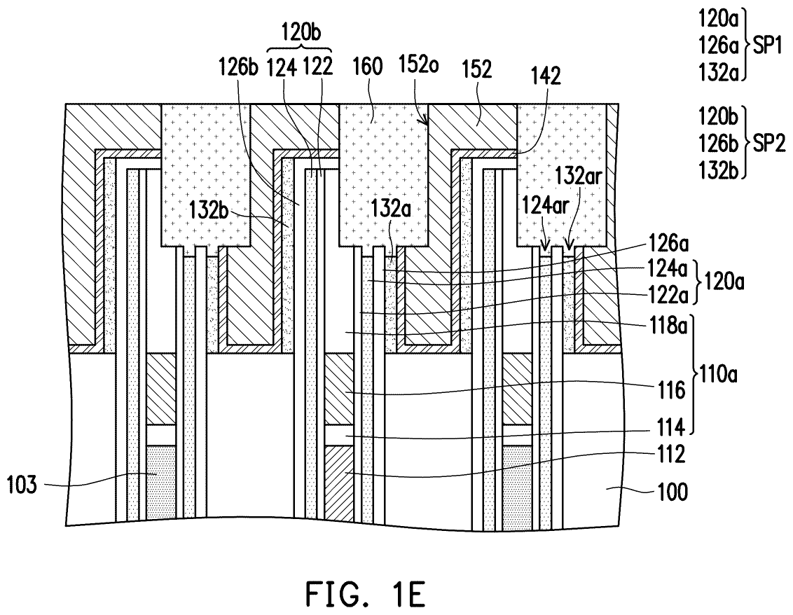

Firstly, referring to FIG. 1A, a plurality of bit line structures 110 are formed in the substrate 100. The cross-sectional view shown in FIG. 1A may be a cross-section taken along a line that crosses the active region and bit line but does not cross the word line, illustrating the bit line structures 110 adjacent to the bit line structure 110 on the conductive contact 112 shown in FIG. 1A being respectively on the pattern layers 103. Each bit line structure 110 may include a barrier pattern 114, a bit line 116 formed on the barrier pattern 114, and a capping layer 118 formed on the bit line 116 and protruding above a top surface of the substrate 100.

The substrate 100 may include a semiconductor substrate or a semiconductor-on-insulator (SOI) substrate. The semiconductor materials in the semiconductor substrate or the SOI substrate may include an element semiconductor, an alloy semiconductor, or a compound semiconductor. The semiconductor materials may be doped with a dopant of a first conductivity type or a dopant of a second conductivity type complementary to the first conductivity type. For example, the first conductivity type may be p-type, whereas the second conductivity type may be n-type. The substrate 100 may also include an isolation structure formed in the semiconductor substrate or the SOI substrate to define active regions, source/drain regions formed in the semiconductor substrate or the SOI substrate, or components such as word lines, dielectric layers, and wiring layers formed on or formed in the semiconductor substrate or the SOI substrate.

The pattern layer 103 may include suitable materials such as polysilicon. The conductive contact 112 may include conductive materials such as metals or metal alloys. The metals and metal alloys may be, for example, Cu, Al, Ti, Ta, W, Pt, Cr, Mo, or alloys thereof. The material of the barrier pattern 114 may include but not limited to titanium nitride (TiN). The bit line 116 may include conductive materials such as metals or metal alloys. The metals and metal alloys may be, for example, Cu, Al, Ti, Ta, W, Pt, Cr, Mo, or alloys thereof. The capping layer 118 may include nitrides such as silicon nitride.

A first spacer 120 is formed on two opposite sidewalls of each bit line structure 110. Each first spacer 120 includes a first material layer 122 and a second material layer 124 formed on the first material layer 122. The first material layer 122 may include nitrides such as silicon nitride (SiNₓ). The second material layer 124 may include oxides such as silicon oxide (SiOₓ).

A second spacer layer 126 is formed on the two opposite sidewalls of each bit line structure 110 to cover the first spacer 120 and a top surface of the capping layer 118. The second spacer layer 126 may include nitrides such as silicon nitride (SiNₓ). In this embodiment, the second spacer layer 126 covering the top surface of the capping layer 118 is beneficial for maintaining the top profile of the bit line structure 110 as a rectangular shape, so as to prevent the bit line structure 110 from having a tapered profile at the top, causing portions of the conductive pad layer (e.g., the conductive pad layer including the barrier layer 140 and the conductive layer 150 as shown in FIG. 1B) that are intended to be removed to be remained due to an insufficient tolerance of the overlay shift in the subsequent patterning processes for the conductive pad layer, and thereby resulting defects such as short circuits.

A third spacer 130 covering the second spacer layer 126 is formed on the two opposite sidewalls of each bit line structure 110 on the top surface of the substrate 100. The third spacer 130 may include oxides such as silicon oxide (SiOₓ). The third spacer 130 may be formed, for example, after the storage node contact is formed. The third spacer 130 may be formed by the following steps. Firstly, a spacer material layer (not shown) covering the second spacer layer 126 is formed on the top surface of the substrate 100 through a process such as atomic layer deposition (ALD) after the storage node contact is formed. Then, portions of the spacer material layer on the top surface of the substrate 100 and above the top surface of the bit line structure 110 are removed through a process such as an etch back process to form the third spacer 130 covering portions of the second spacer layer 126 on the two opposite sidewalls of the bit line structure 110.

Materials of the first material layer 122 and the second spacer layer 126 are different from materials of the second material layer 124 and the third spacer 130. The materials of the first material layer 122 and the second spacer layer 126 include nitrides (e.g., silicon nitride such as SiN or SiCN), and the materials of the second material layer 124 and the third spacer 130 include oxides (e.g., silicon oxide such as SiOx or SiCOx).

Then, referring to FIG. 1B, a conductive pad layer is formed on the top surface of the substrate 100, covering the bit line structures 110, the third spacer 130, the second spacer layer 126, and the first spacer 120. The conductive pad layer includes a barrier layer 140 and a conductive layer 150 formed on the barrier layer 140. The barrier layer 140 may include but not limited to titanium nitride (TiN). The conductive layer 150 may include conductive materials such as metals or metal alloys. The metals and metal alloys may be, for example, Cu, Al, Ti, Ta, W, Pt, Cr, Mo, or alloys thereof.

After that, referring to FIG. 1C, the conductive pad layer is patterned to form a plurality of conductive pad structures, wherein each conductive pad structure includes a barrier pattern 142 and a conductive pattern 152 formed on the barrier pattern 142. In the case where the semiconductor structure is applied to a dynamic random access memory, the conductive pad structure may serve as a landing pad for connecting a storage node (e.g., a capacitor). In the aforementioned patterning processes, the third spacer 130 can enhance the tolerance in an aspect of overlay shift in the aforementioned patterning processes, so as to prevent the portions of the conductive pad layer (including the barrier layer 140 and the conductive layer 150) that are intended to be removed from remaining due to the overlay shift, so that the short circuit issues (e.g., short circuit issues between the landing pad and the storage node contact) caused by the residual barrier layer 140 can be avoided. In other words, the third spacer 130 formed to cover the second spacer layer 126 on the two opposite sidewalls of each bit line structure 110 on the top surface of the substrate 100 can provide an improved process margin for the subsequent patterning processes for forming the conductive pad structures.

As shown in FIG. 1C, in a step of patterning the conductive pad layer, a portion of the first spacer 120, a portion of the second spacer layer 126, and a portion of the third spacer 130 on one of the two opposite sidewalls of each bit line structure 110 are also removed, so as to form a first spacer structure SP1 on one of the two opposite sidewalls of each bit line structure 110a and to form a second spacer structure SP2 on another one of the two opposite sidewalls of each bit line structure 110a. The first spacer structure SP1 may include a first spacer 120a, a second spacer 126a, and a third spacer 132a. The first spacer 120a includes a first material layer 122a and a second material layer 124a. The second spacer structure SP2 may include a first spacer 120b, a second spacer 126b, and a third spacer 132b. A top surface of the first spacer structure SP1 is lower than a top surface of the second spacer structure SP2.

As shown in FIG. 1C, in the step of patterning the conductive pad layer, a portion of each capping layer 118 is also removed, such that the capping layer 118a is formed to include a first portion and a second portion, wherein the first portion has a top surface at a level identical to a level of the top surface of the first spacer structure SP1, while the second portion has a top surface at a level lower than a level of the top surface of the second spacer structure SP2.

Then, referring to FIG. 1C and FIG. 1D, a portion of the second material layer 124a and portion of the third spacer 132a in each first spacer structure SP1 that are exposed by an opening 152o separating the conductive pad structures are removed to form recesses 124ar and 132ar. The portion of the second material layer 124a and the portion of the third spacer 132a in each first spacer structure SP1 exposed by the opening 152o are removed to form the recesses 124ar and 132ar by using a diluted hydrofluoric acid.

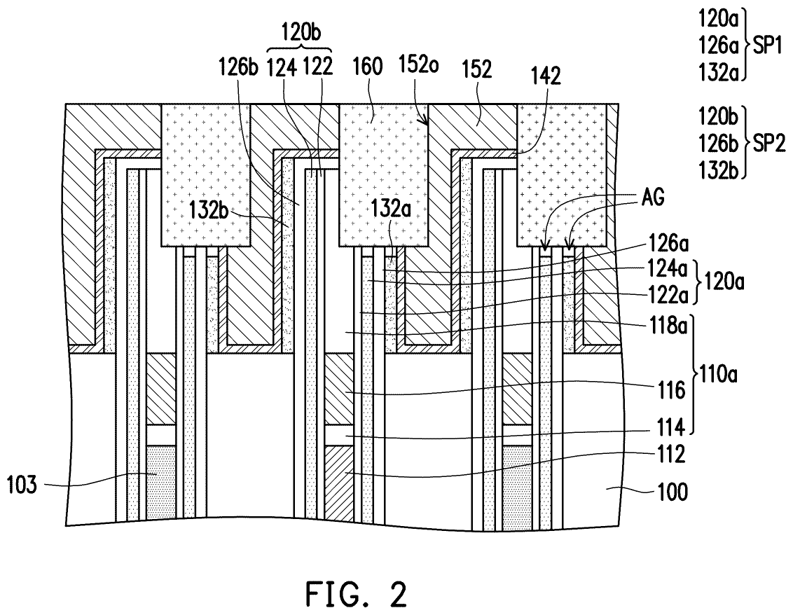

After that, referring to FIG. 1D and FIG. 1E, an insulation pattern 160 is formed in the openings 152o separating the conductive pad structures, wherein the insulation pattern 160 is in contact with the first spacer structure SP1. As shown in FIG. 1E, the insulation pattern 160 may fill the recesses 124ar and 132ar. As shown in FIG. 2, in a step of forming the insulation pattern 160, the insulation pattern 160 is formed above the recesses 124ar and 132ar without filling up the recesses 124ar and 132ar, such that air gaps AG are formed in the recesses 124ar and 132ar. As a result, such configurations may be beneficial for improving the stability of the semiconductor structure.

Each conductive pad structure (e.g., a conductive pad structure including a conductive pattern 152 on a barrier pattern 142) includes an upper portion and a lower portion, wherein the upper portion has a top surface at a level identical to a level of the top surface of the insulation pattern 160, while the lower portion has a top surface at a level identical to a level of the top surface of the first spacer structure SP1.

In summary, in the above method of forming the semiconductor device, the third spacer is additionally formed to cover the second spacer layer on opposite sidewalls of each bit line structure on the top surface of the substrate, so that the subsequent patterning processes for forming the conductive pad structures have an improved process window. For example, the third spacer can enhance the tolerance for overlay shift in the patterning processes, so that the portions of the conductive pad layer intended to be removed will not be remained due to the overlay shift, and the defects such as short circuits can be avoided accordingly.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for forming a semiconductor structure, comprising:
forming a plurality of bit line structures in a substrate, wherein each bit line structure comprises a bit line and a capping layer formed on the bit line and protruding above a top surface of the substrate;
forming a first spacer on opposite sidewalls of each bit line structure;
forming a second spacer layer, on the opposite sidewalls of each bit line structure, covering the first spacer and a top surface of the capping layer;
forming a third spacer, on the top surface of the substrate, covering the second spacer layer on opposite sidewalls of each bit line structure;
forming a conductive pad layer, on the top surface of the substrate, covering the plurality of bit line structures, the third spacer, the second spacer layer, and the first spacer; and
patterning the conductive pad layer to form a plurality of conductive pad structures.

2. The method according to claim 1, wherein each first spacer comprises a first material layer and a second material layer formed on the first material layer.

3. The method according to claim 2, wherein materials of the first material layer and the second spacer layer are different from materials of the second material layer and the third spacer.

4. The method according to claim 3, wherein the materials of the first material layer and the second spacer layer comprise nitride, and the materials of the second material layer and the third spacer comprise oxide.

5. The method according to claim 4, wherein in a step of patterning the conductive pad layer, a portion of the first spacer, a portion of the second spacer layer, and a portion of the third spacer that are located on one of the opposite sidewalls of each bit line structure are also removed to form a first spacer structure on the one of the opposite sidewalls of each bit line structure and to form a second spacer structure on another one of the opposite sidewalls of each bit line structure.

6. The method according to claim 5, wherein a top surface of the first spacer structure is lower than a top surface of the second spacer structure.

7. The method according to claim 6, wherein in the step of patterning the conductive pad layer, a portion of each capping layer is also removed, such that the capping layer is formed to comprise:
a first portion having a top surface positioned at a level identical to a level of the top surface of the first spacer structure; and
a second portion having a top surface positioned at a level lower than a level of the top surface of the second spacer structure.

8. The method according to claim 6, further comprising:
forming an insulation pattern in an opening separating the plurality of conductive pad structures, wherein the insulation pattern is in contact with the first spacer structure.

9. The method according to claim 8, further comprising:
before forming the insulation pattern, removing a portion of the second material layer and a portion of the third spacer in each first spacer structure that are exposed by the opening to form recesses.

10. The method according to claim 9, wherein in a step of forming the insulation pattern, the insulation pattern is formed above the recesses without filling up the recesses, so that air gaps are formed in the recesses.

11. The method according to claim 8, wherein each conductive pad structure comprises:
an upper portion having a top surface positioned at a level identical to a level of a top surface of the insulation pattern; and
a lower portion having a top surface positioned at a level identical to a level of the top surface of the first spacer structure.

12. A semiconductor structure, comprising:
a bit line structure in a substrate, wherein the bit line structure comprises a bit line and a capping layer on the bit line and protruding above a top surface of the substrate;
a first spacer structure on a first sidewall of the bit line structure;
a second spacer structure on a second sidewall of the bit line structure opposite to the first sidewall;
an insulation pattern on the first spacer structure; and
a conductive pad structure on the second spacer structure,
wherein the first spacer structure and the second spacer structure comprise first spacers respectively on the first sidewall and the second sidewall of the bit line structure, and the first spacer of the first spacer structure comprises a top surface lower than a top surface of the first spacer of the second spacer structure, and the top surface of the first spacer of the second spacer structure is positioned at a level identical to a top surface of the capping layer of the bit line structure.

13. The semiconductor structure according to claim 12, wherein the first spacer structure and the second spacer structure comprise second spacers respectively on the first spacers and third spacers respectively on the second spacers, wherein the second spacer of the second spacer structure covers the top surface of the first spacer of the second spacer structure and the top surface of the capping layer of the bit line structure.

14. The semiconductor structure according to claim 13, wherein each of the first spacers comprises a first material layer and a second material layer on the first material layer, and materials of the first material layer and the second spacer are different from materials of the second material layer and the third spacer.

15. The semiconductor structure according to claim 14, wherein the materials of the first material layer and the second spacer comprise nitride, and the materials of the second material layer and the third spacer comprise oxide.

16. The semiconductor structure according to claim 12, wherein a top surface of the first spacer structure is lower than a top surface of the second spacer structure.

17. The semiconductor structure according to claim 14, wherein
the second material layer and the third spacer in the first spacer structure comprises recesses having bottom surfaces lower than top surfaces of the first material layer and the second spacer.

18. The semiconductor structure according to claim 17, wherein the insulation pattern comprises portions filling into the recesses.

19. The semiconductor structure according to claim 17, wherein the insulation pattern is configured above the recesses, so as to define air gaps in the recesses.

20. The semiconductor structure according to claim 17, wherein each conductive pad structure comprises:
an upper portion having a top surface positioned at a level identical to a level of a top surface of the insulation pattern; and
a lower portion having a top surface positioned at a level identical to a level of the top surface of the first spacer structure.
